(19) United States
(12) Patent Application Publication
(10) Pub. No.: US 2024/0180041 A1
(43) Pub. Date: May 30, 2024

(54) HETEROJUNCTION SEMICONDUCTOR SUBSTRATE WITH EXCELLENT DIELECTRIC PROPERTIES, METHOD OF MANUFACTURING THE SAME AND ELECTRONIC DEVICE USING THE SAME

(71) Applicant: KOREA INSTITUTE OF SCIENCE AND TECHNOLOGY, Seoul (KR)

(72) Inventors: Seung Hyub BAEK, Seoul (KR); Soo Young JUNG, Seoul (KR); Sunghoon HUR, Seoul (KR); Ji-Soo JANG, Seoul (KR); Jungho YOON, Seoul (KR); Hyun-Cheol SONG, Seoul (KR); Seong Keun KIM, Seoul (KR); Chong Yun KANG, Seoul (KR); Ji-Won CHOI, Seoul (KR); Jin Sang KIM, Wanju-gun (KR)

(73) Assignee: KOREA INSTITUTE OF SCIENCE AND TECHNOLOGY, Seoul (KR)

(21) Appl. No.: 18/522,771

(22) Filed: Nov. 29, 2023

(30) Foreign Application Priority Data
Nov. 30, 2022 (KR) 10-2022-0163664

(51) Int. Cl. H10N 30/00; C30B 23/04; C30B 29/22; H10N 30/072; H10N 30/082; H10N 30/853

(52) U.S. Cl. CPC H10N 30/10513; C30B 23/04; C30B 29/22; H10N 30/072; H10N 30/082; H10N 30/8536; H10N 30/8548; H10N 30/8561

(57) ABSTRACT

The present invention relates to a heterojunction semiconductor substrate having excellent dielectric properties, a method of manufacturing the same, and an electronic device using the same. The present invention provides a heterojunction semiconductor substrate with improved interlayer adhesion, low leakage current, and excellent dielectric properties that maintain strength in a ferroelectric fatigue experiment by interposing a metal layer and a conductive metal oxide layer on a semiconductor substrate to form an epitaxial oxide thin film layer composed of perovskite piezoelectric oxide. The heterojunction semiconductor substrate can be applied to sensors, actuators, transducers, or MEMS devices that use the high functionality of the high-quality epitaxial oxide thin film layer, including applications in electronic and optical devices.

### CROSS REFERENCE TO RELATED APPLICATION

The present application claims the benefit under 35 USC 119(a) of Korean Patent Application No. 10-2022-0163664 filed on Nov. 30, 2022, in the Korean Intellectual Property Office, the entire contents of which is incorporated herein for all purposes by this reference.

### BACKGROUND OF THE INVENTION

### Field of the Invention

The present invention relates to a heterojunction semiconductor substrate having excellent dielectric properties, a method of manufacturing the same, and an electronic device using the same, more particularly, to a heterojunction semiconductor substrate having excellent dielectric properties, a method of manufacturing the same, and an electronic device using the same, in which a metal layer and a conductive metal oxide layer are interposed on the semiconductor substrate to form an epitaxial oxide thin film layer formed of a perovskite ferroelectric or piezoelectric oxide, which improves interlayer adhesion, reduces leakage current, suppresses dielectric breakdown, and maintains ferroelectric performance even after high-repetition polarization switching in a ferroelectric fatigue test.

### Description of the Related Art

Oxides, which are composed of bonds between oxygen and one or more metal ions, have multiple functionalities and can be applied to electrical, electronic, magnetic, optical, energy, and other devices.

In general, the properties of oxides are optimal when they are in single crystal form, and when these high-quality oxides are applied to devices, it is possible to develop electronic devices with breakthrough performance and functionality that have never existed before.

Since most of the electronics industry is now based on silicon materials, the technical need to combine high-quality functional oxides with silicon substrates is very high.

Single crystal oxides are manufactured by a method of manufacturing a bulk single crystal using Bridgeman, solid-phase single crystal growth method, or the like, and by a method of manufacturing a single crystal thin film in the form of an epitaxial oxide thin film using a sputter, CVD, sol-gel process, or the like.

Meanwhile, since most of the electronics industry is moving toward the development of microscale and nanoscale devices, the functional oxides to be used are preferably in the form of thin films rather than bulk.

As part of this effort, the crystal structure-matched deposition of YSZ(001) on silicon SiO₂/Si(001) substrates and the effect on epitaxial growth after deposition of a YSZ buffer layer have been reported in the non-patent document, and in addition, various buffer layers such as YSZ and SrTiO₃ have been developed to form functional oxide single crystal thin films on silicon substrates. However, due to differences in crystal structure and interatomic bonding features, there is a problem in that the grown epitaxial oxide thin films have a very high defect density compared to silicon single crystals.

It is also very difficult to control the crystal orientation of epitaxial oxide thin films by direct growth. For example, it is impossible to deposit perovskite functional oxide with (110) or (111) orientation on a (001) Si substrate by the direct growth method, or even if it is possible, there is a problem of very poor crystallinity.

Nevertheless, since the properties of functional oxides are strongly dependent on the crystal orientation, the technology to form functional oxides with different orientations on semiconductor substrates is very important.

The patent document is an invention relating to a method of manufacturing a semiconductor substrate and a method of manufacturing a semiconductor device, and reports that a semiconductor substrate having a single crystal semiconductor layer with good properties can be manufactured without requiring CMP treatment or high temperature heat treatment by using a method of separating an interface of a first single crystal semiconductor layer and a second single crystal semiconductor layer formed by a vapor phase epitaxial growth method.

In addition, other technologies for transferring epitaxial oxide thin films have been reported, but they all have reported processes only for separating the thin film from the substrate and manufacturing a free-standing membrane. Thin film membranes transferred to heterogeneous substrates (silicon, glass, etc.) are very weakly bonded to the substrate by van der Waals forces, which causes a problem in that large area processing is difficult.

However, in order to actually manufacture a device, there needs to be a perfect bond between the silicon substrate and the functional oxide thin film.

Accordingly, the present inventor has attempted to solve the conventional problems from a result in which a very high-quality epitaxial thin film can be grown when a functional oxide with similar crystal structure and properties is grown on an oxide single crystal substrate. After a sacrificial layer and an epitaxial oxide thin film of a perovskite structure are grown by vacuum deposition on an oxide single crystal substrate, a conductive metal oxide layer and a metal layer are formed. Further, a metal layer is prepared on a separate semiconductor substrate. Then, the metal layer on the oxide single crystal substrate and the metal layer on the semiconductor substrate are bonded to face each other. After the bonding, the sacrificial layer only is selectively etched and removed, and the oxide single crystal substrate is separated. Thereby, the metal layer and the conductive metal oxide layer are inserted in the middle of the semiconductor substrate and the epitaxial oxide thin film layer. Therefore, the present inventors have completed the present invention by confirming the characteristics in which an interlayer adhesion is improved, a leakage current is lowered, a dielectric breakdown is suppressed, and in ferroelectric fatigue experiments, ferroelectric performance is maintained even with highly repetitive polarization switching.

### DOCUMENTS OF RELATED ART

### Patent Document

Korean Patent No. 1582247

### Non-Patent Document

Japanese Journal of Applied Physics 2004, 43, 1532˜1535.

### SUMMARY OF THE INVENTION

An object of the present invention is to provide a heterojunction semiconductor substrate having excellent dielectric properties by bonding an epitaxial oxide thin film layer using a metal layer and a conductive metal oxide layer formed on a semiconductor substrate.

Another object of the present invention is to provide a method of manufacturing a heterojunction semiconductor substrate.

Still another object of the present invention is to provide an electronic device that is applicable to sensors, actuators, and MEMS devices including a heterojunction semiconductor substrate.

The present invention is directed to providing a heterojunction semiconductor substrate with excellent dielectric properties including a semiconductor substrate, a metal layer, a conductive metal oxide layer, and an epitaxial oxide thin film layer.

The conductive metal oxide layer includes a metal capable of forming a Schottky contact with the epitaxial oxide thin film layer, and more particularly includes a metal having a work function of 5.0 eV or more.

The conductive metal oxide layer may be amorphous or crystalline.

In the heterojunction semiconductor substrate of the present invention, the metal layer is a monolayer or laminated structure composed of one or two or more elements selected from the group consisting of Au, Al, W, Ti, Cr, Pt, Cu, Ni, Mo, Ta, Nb, and La.

The laminated structure is an A layer/B layer/A′ layer structure, in which the A layer and the A′ layer may be the same or different, and any one selected from the group consisting of Ti, Cr, Cu, Ni, Pt and Cr, and in which the B layer is formed of any one selected from the group consisting of Au, Mo, Ta, Nb, La, W and CuW.

In addition, when the metal layer is a laminated structure of an A layer/B layer/A′ layer, the A layer and the A′ layer are formed of a metal adhesion layer with a thickness of 5 to 20 nm, and the B layer is formed of a metal bonding layer with a thickness of 20 nm to 1 μm.

A total thickness of the metal layer is preferably between 5 and 1500 nm.

In the heterojunction semiconductor substrate, the epitaxial oxide thin film layer is formed of a high-quality functional single crystal oxide having a crystallinity with a full width at half maximum (FWHM) value of 0.3° or less when an omega (ω) rocking curve is measured for a peak with the highest diffraction peak intensity, in case of the measurement with a θ−2θ mode of an X-ray diffractometer.

In addition, the single crystal oxide is formed of a perovskite ferroelectric or piezoelectric oxide having a lattice constant of 0.3 to 0.45 nm, and the perovskite piezoelectric oxide includes a material in which any one selected from the group consisting of Pb(Mg_{1/3},Nb_{2/3})O₃, PbZrO₃, PbTiO₃, SrTiO₃, SrRuO₃, BaTiO₃ and BiFeO₃, a solid solution thereof, or a dopant has been added.

In the heterojunction semiconductor substrate of the present invention, the epitaxial oxide thin film layer is formed of a perovskite piezoelectric oxide including zirconium (Zr) grown by a solid phase growth method, and is a poreless thin film layer using the same. In this case, a thin film thickness of the epitaxial oxide thin film layer can be formed from a single unit cell height (0.4 nm or less) to tens of μm.

In addition, the present invention provides a method of manufacturing a heterojunction semiconductor substrate.

There is provided a method of manufacturing a heterojunction semiconductor substrate 1 according to a preferred first embodiment, the method includes: preparing a semiconductor substrate 10 and an oxide single crystal substrate 50; forming a sacrificial layer 40, an epitaxial oxide thin film layer 30, a conductive metal oxide layer 200, and a metal layer 20A sequentially on the oxide single crystal substrate 50; forming a metal layer 20B on the semiconductor substrate 10; bonding the metal layer 20A on the oxide single crystal substrate and a metal layer 20B on the semiconductor substrate such that the metal layer 20A and the metal layer 20B face each other; and separating the oxide single crystal substrate 50 by etching and removing the sacrificial layer 40 after the bonding.

In addition, there is provided a method of manufacturing a heterojunction semiconductor substrate 2 according to a second embodiment, the method includes: preparing a semiconductor substrate 10 and an oxide single crystal substrate 50; forming a sacrificial layer 40, an epitaxial oxide thin film layer 30, a conductive metal oxide layer 201, and a metal layer 21A sequentially on the oxide single crystal substrate 50; patterning the epitaxial oxide thin film layer 30, the conductive metal oxide layer 201, and the metal layer 21A that have been formed into a plurality of lattice cells; forming a metal layer 21B on the semiconductor substrate 10; bonding the metal layer 21A on the oxide single crystal substrate and the metal layer 21B on the semiconductor substrate such that the metal layer 21A and the metal layer 21B face each other; and separating the oxide single crystal substrate 50 by etching and removing the sacrificial layer 40 after the bonding.

In the method of manufacturing the heterojunction semiconductor substrates 1 and 2, the semiconductor substrate uses any one selected from a silicon (Si) substrate, a silicon on insulator (SOI), a sapphire substrate, a GaAs, AlN, Ge, SiGe, GaN, AlGaN, SiC, or AlSiC wafer, a Ni, Cu, Nb, Mo, Ta, La, CuW, NiW, or NiCu plate, or a laminated structure including a plate material described above. In addition, a Si substrate or SOI substrate on which a complementary metal-oxide-semiconductor (CMOS) based circuit is formed may be used on the Si blank substrate.

In the present invention, any one selected from the group consisting of SrTiO₃, DyScO₃, GdScO₃, TbScO₃, EuScO₃, SmScO₃, NdScO₃, PrScO₃, CeScO₃, LaScO₃, LaLuO₃, NdGaO₃, LaGaO₃, SrLaGaO₄ and LaAlO₃ is used as the oxide single crystal substrate.

The oxide single crystal substrate may be surface treated to a surface roughness of 1 nm or less.

In the method of manufacturing the heterojunction semiconductor substrates 1 and 2, the step of bonding is performed in a manner in which the metal layers of each substrate are aligned to face each other at the same position, mechanically bonded, and then pressed and heated.

Further, the present invention provides an electronic device including a semiconductor substrate on which an epitaxial oxide thin film layer is heterojunctionally bonded by a metal layer and a conductive metal oxide layer.

The electronic device may be applied to any one device selected from the group consisting of sensors, actuators, transducers, and MEMS devices, due to the high quality of the piezoelectric single crystal, in addition to manufacturing of conventional electrical, electronic, and optical devices.

According to the present invention, it is possible to provide a heterojunction semiconductor substrate in which a metal layer and a conductive metal oxide layer are interposed on a semiconductor substrate to form an epitaxial oxide thin film layer formed of a perovskite piezoelectric oxide.

In addition, the heterojunction semiconductor substrate of the present invention implements excellent interlayer adhesion and low leakage current to suppress dielectric breakdown while bonding an epitaxial oxide thin film layer on a semiconductor substrate through a transfer method, and excellent dielectric properties that maintain ferroelectric performance even after high repetitive polarization switching in a ferroelectric fatigue experiment.

Therefore, in the manufacturing method of the present invention, a perfect bonding between the semiconductor substrate and the epitaxial oxide thin film layer is achieved, thus enabling a large-area process.

In addition, in case of the epitaxial oxide thin film layer, the interaction with the semiconductor substrate facilitates the control of crystal orientation and domain structure, and in particular, the piezoelectric single crystal with the perovskite-like crystal structure (ABO3) is included, thereby enabling the manufacturing of sensors, actuators, transducers, or microelectromechanical systems (MEMS) devices, including electrical or electronic devices and optical devices.

### BRIEF DESCRIPTION OF THE DRAWINGS

FIG. 1 is a schematic cross-sectional view of a heterojunction semiconductor substrate of the present invention.

FIG. 2 is a schematic cross-sectional view of another form of heterojunction semiconductor substrate of the present invention.

FIG. 3 illustrates results of dielectric properties of a substrate having a sacrificial layer, an epitaxial oxide thin film layer formed on an oxide single crystal substrate prior to transfer according to a manufacturing method of the present invention.

FIG. 4 illustrates results of dielectric properties of a heterojunction semiconductor substrate according to Comparative example 1 of the present invention.

FIG. 5 illustrates results of dielectric properties of a heterojunction semiconductor substrate according to Comparative example 2 of the present invention.

FIG. 6 illustrates results of dielectric properties of a heterojunction semiconductor substrate according to Example 1 of the present invention.

FIG. 7 is a process flowchart of a method of manufacturing a heterojunction semiconductor substrate 1 of the present invention.

FIG. 8 is a process flowchart of a method of manufacturing a heterojunction semiconductor substrate 2 of the present invention.

### DETAILED DESCRIPTION OF THE INVENTION

Hereinafter, the present invention will be described in detail.

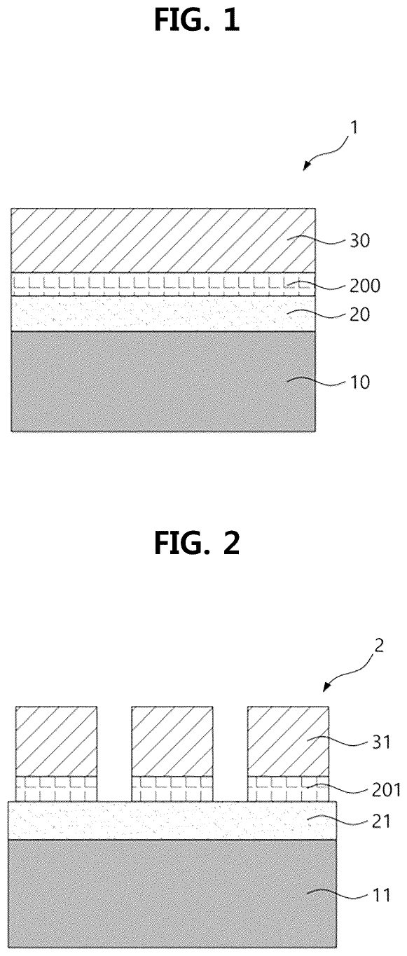

FIG. 1 is a schematic cross-sectional view of a heterojunction semiconductor substrate of the present invention, which provides a heterojunction semiconductor substrate 1 that includes a semiconductor substrate 10, a metal layer 20, a conductive metal oxide layer 200, and an epitaxial oxide thin film layer 30.

FIG. 2 is a schematic cross-sectional view of another form of heterojunction semiconductor substrate of the present invention, which provides a heterojunction semiconductor substrate 2 having a structure in which a metal layer 21, a conductive metal oxide layer 201, and an epitaxial oxide thin film layer 31 formed on a semiconductor substrate 11 are bonded, but in which the metal layer 21, the conductive metal oxide layer 201, and the epitaxial oxide thin film layer 31 are patterned into a plurality of lattice cells.

The heterojunction semiconductor substrate 2 has the same materials and specifications for the semiconductor substrate, the metal layer, the conductive metal oxide layer, and the epitaxial oxide thin film layer, except for the patterned structure.

Therefore, for the heterojunction semiconductor substrates 1 and 2 of the present invention, one that has excellent electrical or thermal conductivity may be used as the semiconductor substrate 10. Preferably, as the semiconductor substrate 10, one selected from a silicon (Si) substrate, a silicon on insulator (SOI), a sapphire substrate, a GaAs, AlN, Ge, SiGe, GaN, AlGaN, SiC, or AlSiC wafer, a Ni, Cu, Nb, Mo, Ta, La, CuW, NiW, or NiCu plate, or a laminated structure composed of the aforementioned plate materials is used.

In this case, when the semiconductor substrate 10 is a silicon substrate or an SOI substrate, a silicon oxide film or a heterogeneous oxide layer may be provided on the silicon substrate. The embodiments of the present invention will be described using a silicon substrate (Si), but will not be limited thereto.

In addition, as the semiconductor substrate 10, a Si substrate or an SOI substrate on which the CMOS-based application specific integrated circuit (ASIC) circuit is configured may be used.

In case of actual piezoelectric thin films, a form combined with an application specific integrated circuit (ASIC) is usually used in the system to process ultrasonic vibration generation and reception signals, so that when a Si substrate or an SOI substrate configured with a CMOS-based application specific integrated circuit (ASIC) circuit is used as the semiconductor substrate 10 of the present invention, the substrate and the epitaxial oxide are electrically connected and may be driven as a device.

In general, as the electronics industry is based on silicon materials, the high-quality epitaxial oxide thin film layer 30 on the semiconductor substrate 10 is heterojunctionally bonded through perfect bonding, and thus can be manufactured and applied to various devices.

The heterojunction semiconductor substrate of the present invention is a transfer bonding of an epitaxial oxide thin film layer, and by inserting a metal layer 20 and a conductive metal oxide layer 200 between a semiconductor substrate 10 and a high-quality epitaxial oxide thin film layer 30 for interlayer bonding, the interlayer adhesion is improved and excellent dielectric properties such as low leakage current and ferroelectric fatigue strength of being maintained constant are implemented.

In the heterojunction semiconductor substrates 1 and 2 of the present invention, the metal layers 20 and 21 may be a monolayer or laminated structure composed of one or two or more elements selected from the group consisting of Au, Al, W, Ti, Cr, Pt, Cu, Ni, Mo, Ta, Nb, and La.

More preferably, the laminated structure is an A layer/B layer/A′ layer structure, in which the A layer and the A′ layer may be the same or different, and any one selected from the group consisting of Ti, Cr, Cu, Ni, Pt and Cr, and in which the B layer is any one selected from the group consisting of Au, Mo, Ta, Nb, La, W and CuW.

In addition, the metal layers 20 and 21 of the present invention are a laminated structure of A layer/B layer/A′ layer, in which the A layer and A′ layer are metal adhesion layers having a thickness of 5 to 20 nm, and the B layer is a structure formed by a metal bonding layer having a thickness of 20 nm to 1 μm, and the bonding structure of the metal layer bonded after transfer is Ti/Au/Ti, Cu/Mo/Cu, Ni/Mo/Ni, Cu/Ta/Cu, Ni/Ta/Ni, Cu/Nb/Cu, Ni/Nb/Ni, Cu/La/Cu, Ni/La/Ni, Cu/W/Cu, Ni/W/Ni, Cu/CuW/Cu, Ni/CuW/Ni, Pt/Au/Pt, Cr/Au/Cr, Ti/Au/Pt, or the like, and is not limited to the laminated structure above, but may be a combination thereof, and may be symmetrical when laminated, or may include an asymmetrical structure.

A total thickness of the formed metal layer after transfer is preferably between 5 and 1500 nm. In this case, when the thickness of the metal layer is too thin, less than 5 nm, depending on the surface roughness of the substrate or the epitaxial oxide thin film layer to be transferred, the epitaxial oxide thin film layer may not be deposited on the entire surfaces, resulting in low adhesion, and when the thickness exceeds 1500 μm, there is a problem of increasing the price as the thickness increases because precious metals such as Au are used. The metal layer does not need to be too thick, as it should be set to a thickness that can be used as a bottom electrode.

Therefore, in the heterojunction semiconductor substrate of the present invention, the metal layers 20 and 21 may be used as a bottom electrode.

In the heterojunction semiconductor substrates 1 and 2 of the present invention, the conductive metal oxide layers 200 and 201 are in contact with the epitaxial oxide thin film layer 30 to provide a stable leakage current and a constant polarization switching effect as a result of ferroelectric fatigue.

In this case, the conductive metal oxide layer 200 should have conductive properties and a work function value of 5.0 eV or more, more preferably be capable of forming a Schottky contact rather than an Ohmic contact with the adjacent ferroelectric layer 30 or 31. As a result, the leakage current can be lowered to suppress the dielectric breakdown phenomenon, and the movement of oxygen vacancies between the ferroelectrics and the conductive metal oxide layer is facilitated to suppress the ferroelectric fatigue phenomenon. In addition, the excellent adhesion between the conductive metal oxide layer and the ferroelectric layer enables a structure in which the ferroelectric layer is strongly bonded to the semiconductor substrate.

The conductive metal oxide layers 200 and 201 of the present invention use any one selected from the group consisting of SRO SRO(SrRuO₃), RuO₂, and indium tin oxide (ITO), and may be laminated in the amorphous or crystalline state of the materials above.

A thickness of the conductive metal oxide layer does not need to be thick as it is for the purpose of interface control, and the roughness of the surface being deposited will determine a lower limit to the thickness. The thickness of the conductive metal oxide layer does not need to be particularly limited, but may preferably be formed of 5 to 50 nm.

In addition, in the heterojunction semiconductor substrate of the present invention, the epitaxial oxide thin film layer 30 is formed of a high-quality functional single crystal oxide having a crystallinity with a full width at half maximum (FWHM) value of 0.3° or less when an omega (ω) rocking curve is measured for a peak with the highest diffraction peak intensity, in case of the measurement with a θ−2θ mode of an X-ray diffractometer.

Specifically, the single crystal oxide is a perovskite piezoelectric oxide having a lattice constant of 0.3 to 0.45 nm, and in particular, the perovskite piezoelectric oxide includes one composed of a material in which any one selected from the group consisting of Pb(Mg_{1/3}Nb_{2/3})O₃, PbZrO₃, PbTiO₃, SrTiO₃, SrRuO₃, BaTiO₃ and BiFeO₃, a solid solution thereof, or a dopant has been added.

As a specific example, the perovskite piezoelectric oxide is PMN-PT(Pb(Mg_{1/3}Nb_{2/3})O₃—PbTiO₃), PMN-PZT(Pb(Mg_{1/3}Nb_{2/3})O₃—Pb(Zr,Ti)O₃), and especially PMN-PZT(Pb(Mg_{1/3}Nb_{2/3})O₃—Pb(Zr,Ti)O₃) will be described in the embodiment of the present invention. However, from a result that the PMN-PZT thin film, which is an epitaxial oxide thin film layer 30, is smoothly bonded by a metal layer on a semiconductor substrate, a high-quality epitaxial oxide thin film layer 30 can be formed using a piezoelectric single crystal of a perovskite-type crystal structure (ABO₃).

As a piezoelectric single crystal of the perovskite-type crystal structure (ABO₃), a perovskite piezoelectric oxide ([A][(MN)_{1-x-y}TiₓZr_{y}]O₃) containing zirconium (Zr) grown by a solid phase growth method can be used [Published in Korean Patent No. 0743614].

In the formula above, A is at least one species selected from the group consisting of Pb, Sr, Ba, and Bi, M is at least one species selected from the group consisting of Ce, Co, Fe, In, Mg, Mn, Ni, Sc, Yb, and Zn, N is at least one species selected from the group consisting of Nb, Sb, Ta, and W, and x and y each satisfy the following conditions:

0.05≤x≤0.58 (mole fraction) and 0.05≤y≤0.62 (mole fraction)

In addition, in the heterojunction semiconductor substrate of the present invention, in order to provide a high-quality epitaxial oxide thin film layer 30, the epitaxial oxide thin film layer 30 is formed with a piezoelectric single crystal of the perovskite-type crystal structure (ABO3) having the composition of Chemical formula 1 below.

[A_{1-(a+1.5b)}BₐC_{b}][(MN)_{1-x-y}(L)_{y}Tiₓ]O₃ Chemical Formula 1

In the formula above, A is Pb or Ba,
B is one or more species selected from the group consisting of Ba, Ca, Co, Fe, Ni, Sn, and Sr,
C is one or more species selected from the group consisting of Co, Fe, Bi, La, Ce, Pr, Nd, Pm, Sm, Eu, Gd, Tb, Dy, Ho, Er, Tm, Yb, and Lu,
L is a single or mixed form selected from Zr or Hf,
M is one or more species selected from the group consisting of Ce, Co, Fe, In, Mg, Mn, Ni, Sc, Yb, and Zn,
N is one or more species selected from the group consisting of Nb, Sb, Ta, and W, where 0<a≤0.10, 0<b≤0.05, 0.05≤x≤0.58, and 0.05≤y≤0.62.

Preferably, a piezoelectric single crystal satisfying the requirements of 0.01≤a≤0.10 and 0.01≤b≤0.05 in the formula above is used, and more preferably, satisfying a/b≥2. In this case, when a is less than 0.01, the perovskite phase is unstable, and when exceeding 0.10, the phase transition temperature becomes too low, which is not desirable for practical use.

In addition, when the a/b≥2 requirement is not satisfied, dielectric and piezoelectric properties are not maximized or single crystal growth is limited, which is not desirable.

The piezoelectric single crystal of the perovskite-type crystal structure (ABO₃) having the composition of Chemical formula 1, based on the tendency of the piezoelectric properties to further increase as the chemical composition is compounded, in the perovskite-type crystal structure (ABO₃), the [A] position ions are composed of a complex composition of [A_{1-(a+1.5b)}BₐC_{b}]. The composition of A includes leaded or unleaded elements, and embodiments of the present invention will be described with reference to leaded piezoelectric single crystals in which A is Pb, but will not be limited thereto.

In this case, a superior dielectric constant may be implemented in the complex composition of the [A] position ions in a piezoelectric single crystal having the composition of Chemical formula 1 compared to those composed of a metal trivalent element or a metal divalent element alone.

A piezoelectric single crystal having the composition of Chemical formula 1, in the perovskite-type crystal structure (ABO₃), includes a metal tetravalent element in the [B] position ion, but in particular for the L composition, is limited to a singular or mixed form selected from Zr or Hf.

Therefore, the present invention utilizes a piezoelectric single crystal with a uniform composition without a composition gradient, even with a complex chemical composition, by a solid-phase single crystal growth method, and forms an epitaxial oxide thin film layer with a piezoelectric single crystal having dielectric properties of high dielectric constant (K3T), high piezoelectric constants (d33 and k33), high phase transition temperatures (TC and TRT), and high coercive field (EC) through the complex composition of the [A] position ions.

The epitaxial oxide thin film layer 30 of the present invention includes a perovskite piezoelectric oxide including zirconium (Zr) grown by the solid phase growth method, but is characterized in that it is formed of a pore-free thin film even when a perovskite piezoelectric oxide including pores is used in the solid phase growth method process.

A thin film thickness of the epitaxial oxide thin film layer 30 may be formed of 0.4 to tens of μm, and more preferably of 10 μm or more.

The thickness of the epitaxial oxide thin film layer is determined in a manner where a bulk single crystal is cut into the form of a wafer, bonded to a semiconductor substrate, and then polished to match the thickness, thus the thicker the better. Therefore, within the scope of the above-mentioned method, the epitaxial oxide thin film layer may be formed to a thickness that is acceptable in time and economic terms, preferably 10 μm or more, and more preferably 10 to 50 μm.

The heterojunction semiconductor substrates 1 and 2 of the present invention, which are transfer bonded with the laminated structure described above, implement excellent dielectric properties such as a polarization switching effect due to improved interlayer adhesion, low leakage current, and constant ferroelectric fatigue strength.

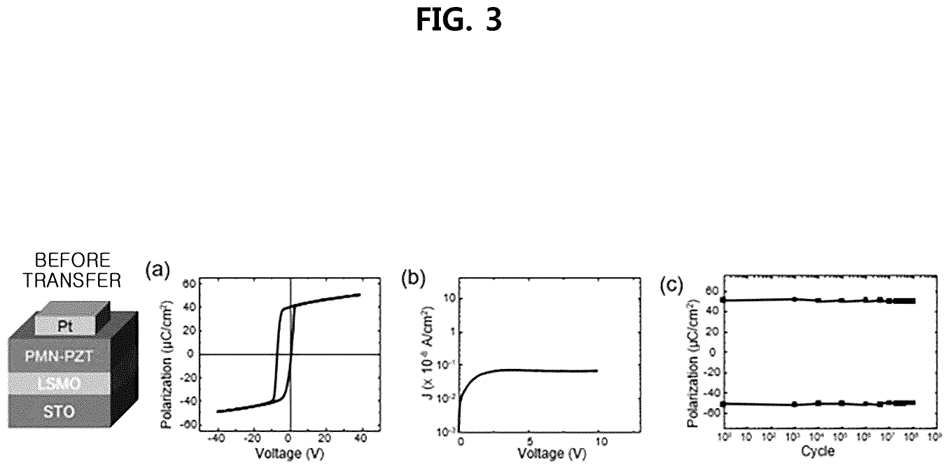

FIG. 3 illustrates results of the dielectric properties of substrate prior to transfer according to the present invention. Specifically, for a substrate with a sacrificial layer (LSMO), epitaxial oxide thin film layer (PMN-PZT) formed on an oxide single crystal (STO) substrate, (a) in the voltage versus polarization graph, the epitaxial oxide thin film layer (PMN-PZT) shows excellent ferroelectric performance with a hysteresis curve shape close to a rectangle, and an imprint characteristic that is horizontally shifted in a negative direction before transfer, (b) the leakage current measurement shows that the leakage current remains constant with a low value, and (c) in the ferroelectric fatigue experiment, the polarization switching behavior is examined by repeatedly applying regularly spaced (+) and (−) voltage cycles, and the results show that the polarization remains almost constant even in the repeated cycles.

Accordingly, the heterojunction semiconductor substrates 1 and 2 of the present invention are designed such that the dielectric properties of the epitaxial oxide thin film layer (PMN-PZT) are retained even after heterojunction on the semiconductor substrate.

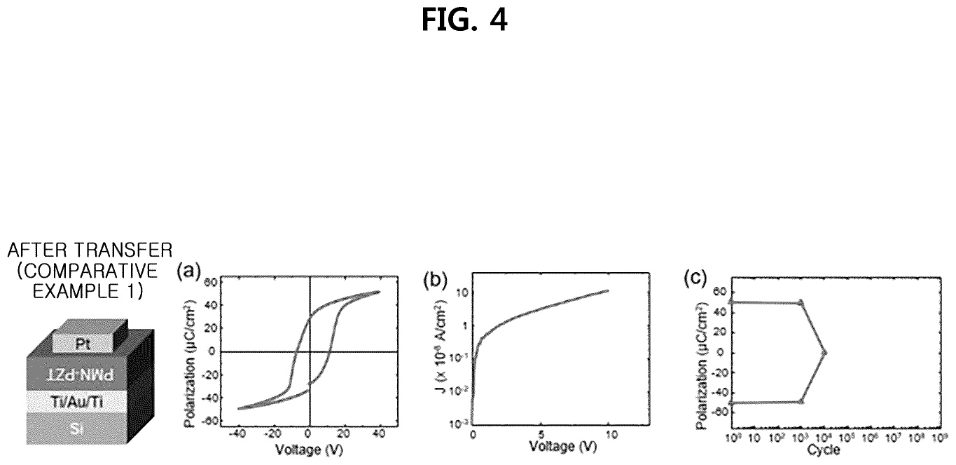

FIG. 4 illustrates results of dielectric properties of a heterojunction semiconductor substrate according to Comparative example 1 of the present invention. The heterojunction semiconductor substrate of Comparative example 1 is formed by the transfer bonding according to the present invention, and is a structure in which a metal layer (Ti/Au/Ti) is interposed on a silicon (Si) substrate and an epitaxial oxide thin film layer (PMN-PZT) is formed on the metal layer.

In the above, the metal layer (Ti/Au/Ti) is in contact with the interfacial Ti layer to improve the adhesion with the silicon (Si) substrate.

As a result, in the heterojunction semiconductor substrate of Comparative example 1, (a) a voltage versus polarization graph shows that the shape of the hysteresis curve is electrically leaky, with the imprint having disappeared due to an increase in the coercive field, and in particular (b) it can be seen that the leakage current tends to increase, which is caused by an ohmic contact at the interface, which occurs due to a low work function of the metal (Ti) in the relationship between the work function of the metal (Pt) in the epitaxial oxide thin film layer (PMN-PZT) and the work function of the metal (Ti) in the metal layer (Ti/Au/Ti) in contact with the metal (Pt). From these results, (c) the dielectric breakdown phenomenon is confirmed by the fact that in the ferroelectric fatigue experiment, the semiconductor substrate withstands up to 10³ and then heats up under the current flowing condition. That is, the substrate cannot serve as a dielectric due to electrical conduction.

To improve these problems, a metal with a work function value higher than the work function of Ti (4.33 eV) is deposited at the interface of the laminated structure of the metal layer (Ti/Au/Ti) in contact with the epitaxial oxide thin film layer (PMN-PZT). Accordingly, in Comparative example 2 of the present invention, as the Pt metal (5.1 eV) is further laminated, a heterojunction semiconductor substrate is provided that is in smooth contact with the metal (Pt) of the epitaxial oxide thin film layer (PMN-PZT) and has a stabilized leakage current value compared to Comparative example 1.

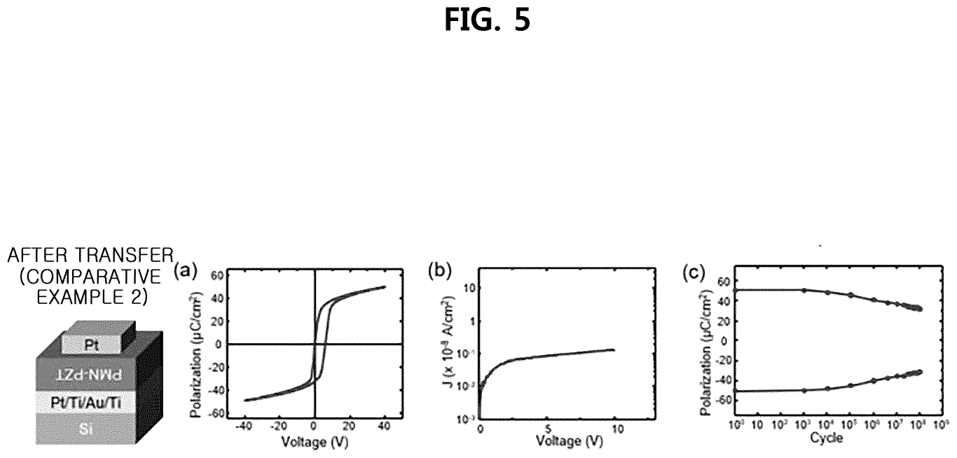

FIG. 5 illustrates results of dielectric properties of a heterojunction semiconductor substrate according to Comparative example 2 of the present invention, and the substrate is a structure in which a metal layer (Pt/Ti/Au/Ti) is interposed on silicon (Si) and an epitaxial oxide thin film layer (PMN-PZT) is formed on the metal layer.

As a result, (a) the voltage versus polarization graph is horizontally shifted in a positive direction after transfer, and (b) low leakage current values are observed, so the requirement for a dielectric is satisfied. However, (c) the ferroelectric fatigue experiment shows that the polarization decreases as the number of cycle repetitions increases, which is attributed to a phenomenon that when the epitaxial oxide thin film layer (PMN-PZT) is in contact with the metal (Pt), defects caused by oxygen vacancies in the oxide are accumulated at the interface, reducing the polarization switching area.

Accordingly, in order to implement perfect bonding by improving adhesion between layers and thereby retaining dielectric properties of the epitaxial oxide thin film layer (PMN-PZT), the metal layer (Ti/Au/Ti) is interposed to improve adhesion with a semiconductor substrate (e.g., Si), and the conductive metal oxide layer (SRO) is disposed to improve adhesion with the epitaxial oxide thin film layer (PMN-PZT) and minimize defects caused by oxygen deficiency.

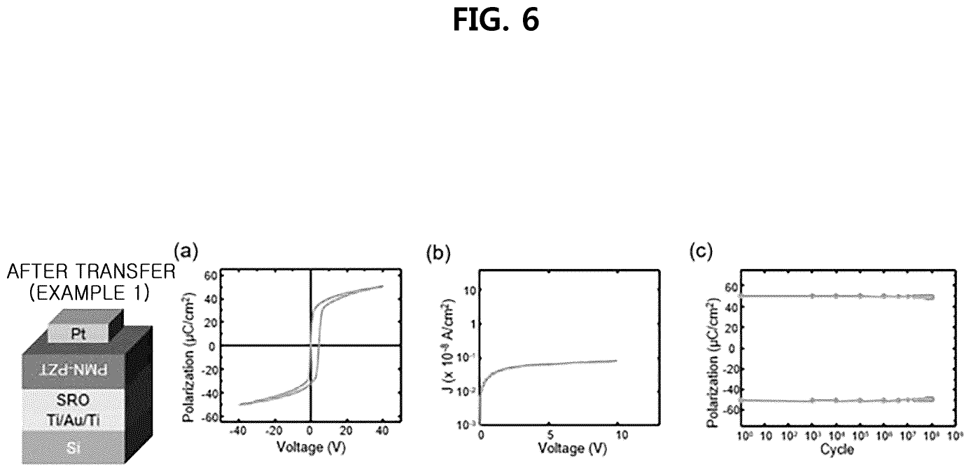

FIG. 6 illustrates results of dielectric properties of a heterojunction semiconductor substrate according to Example 1 of the present invention, and the structure is constituted of a metal layer (Ti/Au/Ti) and a conductive metal oxide layer (SRO) interposed on silicon (Si), on top of which an epitaxial oxide thin film layer (PMN-PZT) is formed. As a result, (a) the voltage versus polarization graph results in a horizontal shift in a positive direction after transfer. This results from the upside down of the PMN-PZT layer during transfer, and the imprint phenomenon is maintained, thus retaining high-quality piezoelectric performance and stability.

In addition, (b) it can be seen that the leakage current value is low, and (c) the defects caused by oxygen vacancies in the oxide at the interface are reduced by the epitaxial oxide thin film layer (PMN-PZT) and the conductive metal oxide layer (SRO). Accordingly, it can be seen that the polarization switching behavior remains constant even after repeated cycles in the ferroelectric fatigue experiment.

From the above, the heterojunction semiconductor substrate of the present invention shows the result that the dielectric properties of the substrate before transfer in FIG. 3 are retained. It means that this result is caused by the perfect interlayer bonding.

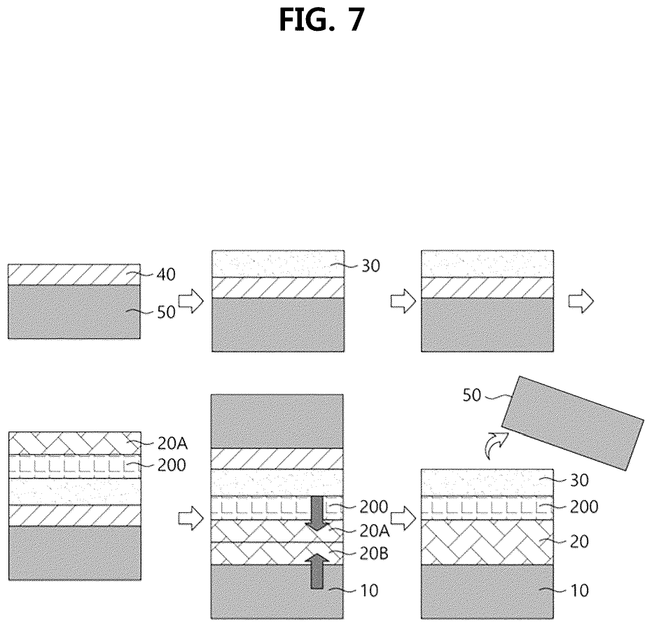

FIG. 7 is a process flowchart of a method of manufacturing a heterojunction semiconductor substrate 1 of the present invention.

There is provided a method of manufacturing a heterojunction semiconductor substrate, the method includes
1) forming a sacrificial layer 40, an epitaxial oxide thin film layer 30, a conductive metal oxide layer 200, and a metal layer 20A on an oxide single crystal substrate 50 sequentially;
2) forming a metal layer 20B on a semiconductor substrate 10,
3) bonding the metal layer 20A on the oxide single crystal substrate 50 and a metal layer 20B on the semiconductor substrate 10 such that the metal layer 20A and the metal layer 20B face each other; and
4) etching and removing the sacrificial layer 40 after the bonding to separate the oxide single crystal substrate 50.

In the method of manufacturing the heterojunction semiconductor substrate 1 of the present invention, in step 1), the semiconductor substrate 10 is selected from a silicon (Si) substrate, a silicon on insulator (SOI), a sapphire substrate, a GaAs, AlN, Ge, SiGe, GaN, AlGaN, SiC, or AlSiC wafer, or a Ni, Cu, Nb, Mo, Ta, La, CuW, NiW, or NiCu plate, or a laminated structure composed of the plate materials described above, the embodiments of the present invention will be described using the silicon substrate, but will not be limited thereto. In addition, a Si substrate or SOI substrate on which the CMOS-based application specific integrated circuit (ASIC) circuit is configured may be used, and the substrate may be electrically connected to the epitaxial oxide to drive as a device.

In addition, the oxide single crystal substrate 50 of step 1) uses a material having a perovskite structure, for example, preferably may use any one selected from the group consisting of SrTiO₃, DyScO₃, GdScO₃, TbScO₃, EuScO₃, SmScO₃, NdScO₃, PrScO₃, CeScO₃, LaScO₃, LaLuO₃, NdGaO₃, LaGaO₃, SrLaGaO₄ and LaAlO₃. At this time, the oxide single crystal substrate 50 is prepared by surface treatment with a surface roughness of 1 nm or less by chemical etching and heat treatment so that the formation of an epitaxial film on an upper portion thereof is favorable.

In the method of manufacturing the heterojunction semiconductor substrate 1 of the present invention, in step 1), a very high-quality epitaxial thin film growth is possible by growing a functional oxide with a similar crystal structure and properties on an oxide single crystal substrate 50. The epitaxial thin film facilitates control of crystal orientation and domain structure due to the interaction with the substrate and may be deposited to have improved crystallinity compared to the bulk single crystal.

Accordingly, the epitaxial sacrificial layer 40 may be formed using a vacuum deposition process on the oxide single crystal substrate 50, and the functional oxide epitaxial thin film 30 to be transferred may be formed on the epitaxial sacrificial layer 40. In this case, the epitaxial sacrificial layer 40 and the oxide epitaxial thin film layer 30 are formed using processes such as sputtering, pulsed laser deposition (PLD), MBE, CVD, evaporator, etc.

In this case, the crystallinity of the oxide epitaxial thin film layer 30 to be transferred to the silicon substrate is characterized by a full width at half maximum (FWHM) value of 0.3° or less when measuring the omega (ω) rocking curve for a peak with the highest diffraction peak intensity, in case of the measurement with the 0−2θmode of an X-ray diffractometer (e.g., the (002) diffraction peak for the (001) orientation).

After the formation of the oxide epitaxial thin film layer 30, a chemical mechanical polishing (CMP) treatment may be further performed to polish the surface.

After the treatment above, the conductive metal oxide layer 200 is formed on the oxide epitaxial thin film layer 30, which in an embodiment of the present invention is described as being formed in an amorphous state at room temperature, but is not limited thereto, and may be deposited in a crystalline state.

In this case, a metal included in the conductive metal oxide layer 200 is preferably selected from the group of materials having a work function higher than that of a metal in the adjacent metal layer 20 and having conductive properties. For example, any one selected from the group consisting of SRO (SrRuO₃), RuO₂ and ITO (Indium tin oxide) may be used, and the embodiments of the present invention will be described using SRO (SrRuO₃), but will not be limited thereto.

After the formation of the conductive metal oxide layer 200, the metal layer 20A may be formed through a method such as sputtering, evaporator, atomic layer deposition (ALD), CVD, or the like.

Specifically, the metal layer 20A may be a monolayer or laminated structure composed of one or two or more elements selected from the group consisting of Au, Al, W, Ti, Cr, Pt, Cu, Ni, Mo, Ta, Nb, and La.

The laminated structure is an A layer/B layer/A′ layer structure, in which the A layer and the A′ layer may be the same or different, and any one selected from the group consisting of Ti, Cr, Cu, Ni, Pt and Cr, and in which the B layer is formed of any one selected from the group consisting of Au, Mo, Ta, Nb, La, W and CuW.

More specifically, the metal layer 20A may be composed of a bonding layer formed of any one selected from the group consisting of Au, Mo, Ta, Nb, La, W, and CuW, which is deposited on a metal adhesion layer formed of any one selected from the group consisting of Ti, Cr, Cu, Ni, Pt, and Cr.

In the method of manufacturing the heterojunction semiconductor substrate 1 of the present invention, step 2) is a step of forming the metal layer 20B on the semiconductor substrate 10.

In this case, in a manner similar to the metal layer formed in step 1), the metal layer 20B forms a metal bonding layer in which any one of Au, Mo, Ta, Nb, La, W, and CuW is deposited on a metal adhesion layer selected from the group consisting of Ti, Cr, Cu, Ni, Pt, and Cr.

The metal layers 20A and 20B may be further surface modified using argon (Ar) or oxygen (O₂) plasma to remove an oxide layer or other contaminants that may form on the surface of the metal layer after the deposition.

Then, step 3) of the method of manufacturing the heterojunction semiconductor substrate 1 of the present invention performs a step of bonding the metal layer 20A on the oxide single crystal substrate and the metal layer 20B on the semiconductor substrate such that the metal layer 20A and the metal layer 20B face each other.

Specifically, the metal layers 20A and 20B are mechanically bonded by aligning them in the same position so that they are oppositely oriented, that is, facing each other, and then bonded by pressing/heating means.

The bonding means may apply a pressure of 0.1 to 10 MPa for 10 seconds to 20 minutes, and a heat of a temperature of 400° C. or less, and the heat may be selectively employed. To increase bonding efficiency, as necessary, each of the metal bonding layers may be treated with Ar or O₂ plasma to remove impurities and activate the surface before pressure is applied.

In this case, the bonding structure of the bonded metal layer 20 after transfer may be formed of any one selected from the group consisting of Ti/Au/Ti, Cu/Mo/Cu, Ni/Mo/Ni, Cu/Ta/Cu, Ni/Ta/Ni, Cu/Nb/Cu, Ni/Nb/Ni, Cu/La/Cu, Ni/La/Ni, Cu/W/Cu, Ni/W/Ni, Cu/CuW/Cu, Ni/CuW/Ni, Pt/Au/Pt, Cr/Au/Cr, and Ti/Au/Pt. The laminated structure described above is just illustrative of a preferred example but the present invention is not limited thereto and may be a combination thereof, and the laminated structure may be symmetrical or include an asymmetrical structure.

In addition, when the bonded metal layer 20 after transfer of the present invention is a laminated structure of an A layer/B layer/A′ layer, the A layer and the A′ layer are formed of a metal adhesion layer with a thickness of 5 to 20 nm, and the B layer is formed of a metal bonding layer with a thickness of 20 nm to 1 μm.

A total thickness of the formed metal layer 20 after transfer is preferably between 5 and 1500 nm.

In step 4) of the method of manufacturing the heterojunction semiconductor substrate 1 of the present invention, the two bonded substrates are placed in an etching solution, and only the sacrificial layer 40 is selectively removed by etching to separate the oxide single crystal substrate 50, thereby manufacturing the semiconductor substrate 10 in which the epitaxial oxide thin film layer 30 is bonded to the metal layer 20.

In this case, the metal layer 20 may be used as a bottom electrode depending on a device, and the separated oxide single crystal substrate 50 may be recycled.

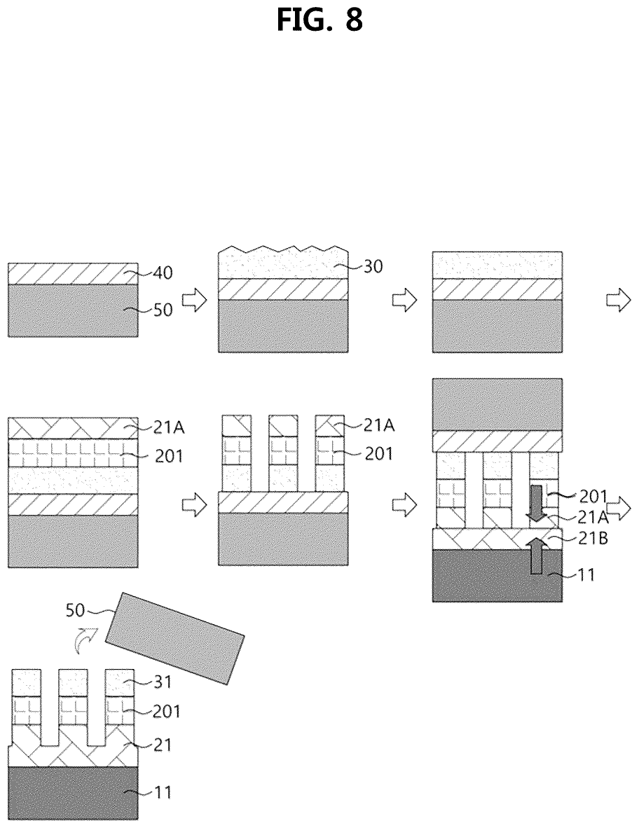

FIG. 8 is a process flowchart of a method of manufacturing a heterojunction semiconductor substrate 2 of the present invention.

There is provided a method of manufacturing a heterojunction semiconductor substrate, the method includes
1) forming a sacrificial layer 40, an epitaxial oxide thin film layer 30, a conductive metal oxide layer 201, and a metal layer 21A on an oxide single crystal substrate 50 sequentially;
3) patterning the epitaxial oxide thin film layer 30, the conductive metal oxide layer 201, and the metal layer 21A formed above into a plurality of lattice cells;
4) forming a metal layer 21B on the semiconductor substrate 10;
5) bonding the metal layer 21A on the oxide single crystal substrate and a metal layer 21B on the semiconductor substrate such that the metal layer 21A and the metal layer 21B face each other; and
6) etching and removing the sacrificial layer 40 after the bonding to separate the oxide single crystal substrate 50.

The method of manufacturing the heterojunction semiconductor substrate 2 of the present invention is the same as the method of manufacturing the heterojunction semiconductor substrate 1, except for the step of patterning the epitaxial oxide thin film layer 30, the conductive metal oxide layer 201, and the metal layer 21A formed on the oxide single crystal substrate 50 into a plurality of lattice cells.

In this case, in the method of manufacturing the heterojunction semiconductor substrate 2, the epitaxial oxide thin film layer 30 may be made in the form of islands with functional epitaxial thin films spaced at certain intervals using a wet etching or dry etching method, and such a structure may be used in the future to improve the etching speed of the sacrificial layer or for isolation purposes to suppress mechanical and electrical mutual interference between each cell.

Therefore, the present invention provides an electronic device including a semiconductor substrate on which an epitaxial oxide thin film layer is heterojunctionally bonded by a metal layer and a conductive metal oxide layer.

Specifically, the heterojunction semiconductor substrate may be applied to electrical and electronic devices, optical devices, as well as sensors, actuators, transducers, or MEMS devices.

Hereinafter, the present invention will be described in more detail with reference to examples.

The examples are intended to describe the present invention more specifically, and the scope of the present invention is not limited to these examples.

### <Example 1> Fabrication 1 of PMN-PZT Single Crystal Piezoelectric Layer/Conductive Metal Oxide Layer (SRO)/Metal Layer (Ti—Au—Ti)/Si

A sacrificial layer of (La_{0.67},Sr_{0.33})MnO₃ (LSMO, 40) of 50 nm was grown as an epitaxial thin film on an SrTiO₃ single crystal substrate 50 through a PLD process. PMN-PZT 1.2 μm was grown as an epitaxial oxide thin film layer 30 by a sputtering process on LSMO, and a CMP process was performed to reduce the surface roughness. A conductive metal oxide layer 200 was formed by introducing SRO (SrRuO₃) in an amorphous state at room temperature on the epitaxial oxide thin film layer 30, and then Ti of 10 nm as a metal bonding layer and Au of 120 nm as a metal transfer layer were sequentially grown by a thermal evaporation process.

A metal layer (Au/Ti) was also formed on the silicon substrate 10 to be transferred using the thermal evaporation process. The Au surfaces formed on the silicon substrate and PMN-PZT were bonded together after oxygen plasma treatment. A pressure of 5 MPa was applied using a press for 15 minutes, and after metal bonding, the specimen was placed in a solution to selectively etch the LSMO sacrificial layer to separate the PMN-PZT layer from the SrTiO₃ substrate and transfer the PMN-PZT layer to the silicon substrate, thus fabricating the heterojunction semiconductor substrate 1.

### <Example 2> Fabrication 2 of PMN-PZT Single Crystal Piezoelectric Layer/Conductive Metal Oxide Layer (SRO)/Metal Layer (Ti—Au—Ti)/Si

The heterojunction semiconductor substrate 2 was fabricated by performing the same as in Example 1 above, except that a 100×100 μm PR (photo resist) pattern was formed on the epitaxial oxide thin film layer 30, the conductive metal oxide layer 200, and the metal layer (Au/Ti) formed on the SrTiO3 single crystal substrate 50 by a photolithography process, and a wet etching process was further performed to etch the conductive metal oxide layer (SRO) and the metal layer (Au/Ti) and the PMN-PZT layer.

### <Comparative Example 1> Fabrication of PMN-PZT Single Crystal Piezoelectric Layer/Metal Layer (Ti—Au—Ti)/Si

A sacrificial layer of (La_{0.67},Sr_{0.33})MnO₃ (LSMO, 40) of 50 nm was grown as an epitaxial thin film on an SrTiO₃ single crystal substrate 50 through a PLD process. PMN-PZT 1.2 μm was grown as an epitaxial oxide thin film layer 30 by a sputtering process on LSMO, and a CMP process was performed to reduce the surface roughness. Then, Ti of 10 nm as a metal bonding layer and Au of 120 nm as a metal transfer layer were sequentially grown by a thermal evaporation process.

A metal layer (Au/Ti) was also formed on the silicon substrate 10 to be transferred using the thermal evaporation process. The Au surfaces formed on the silicon substrate and PMN-PZT were bonded together after oxygen plasma treatment. A pressure of 5 MPa was applied using a press for 15 minutes, and after metal bonding, the specimen was placed in a solution to selectively etch the LSMO sacrificial layer to separate the PMN-PZT layer from the SrTiO₃ substrate and transfer the PMN-PZT layer to the silicon substrate, thus fabricating the heterojunction semiconductor substrate.

### <Comparative Example 2> Fabrication of PMN-PZT Single Crystal Piezoelectric Layer/Metal Layer (PT/Ti—Au—Ti)/Si

The heterojunction semiconductor substrate was fabricated by performing the same as in Comparative example 1 above, except that when Ti of 10 nm as a metal bonding layer and Au of 120 nm as a metal transfer layer were sequentially grown by a thermal evaporation process, Pt was additionally deposited on the metal bonding layer.

### <Experimental Example 1> Evaluation of Ferroelectric Performance of Heterojunction Semiconductor Substrate

For the specimens of the heterojunction semiconductor substrates fabricated in Example 1 and Comparative examples 1 and 2 above, the ferroelectric performance of the materials was evaluated using a Precision Premier II (Radiant Technologies. Inc.) instrument.

As a result, the evaluation results for each substrate are shown in FIGS. 3 to 6. From the graphs of (a) voltage versus polarization before and after transfer of the heterojunction semiconductor substrate of the present invention, it was confirmed that for the heterojunction semiconductor substrate according to Example 1, the PMN-PZT epitaxial oxide thin film layer maintains ferroelectricity well even after transfer.

From FIGS. 3 and 6, it could be confirmed of the leakage current characteristics through (b) the effect on the interfacial adhesion depending on the work function of the metal in the metal layer of the laminated structure formed for improving the adhesion with the semiconductor substrate (Si substrate) and the leakage current results accordingly.

In addition, for the heterojunction semiconductor substrate of Example 1, (c) in the ferroelectric fatigue experiment, the fatigue strength was constantly maintained before and after the transfer bonding, thereby confirming the polarization switching effect.

From the above, it was confirmed that high-quality epitaxial oxide thin film layer 30 was heterojunctionally bonded with perfect bonding on the semiconductor substrate 10 with the conductive metal oxide layer 200 and the metal layer 20 interposed by confirming that the dielectric properties of the heterojunction semiconductor substrate of the transfer bonded structure according to Example 1 of the present invention were retained before and after transfer.

Therefore, when the high-quality epitaxial oxide thin film layer 30 on the semiconductor substrate 10 is heterojunctionally bonded with perfect bonding, the heterojunction semiconductor substrate according to the present invention can be fabricated and applied to a variety of devices, thereby improving the stability of piezoelectric performance when devices such as piezoelectric MEMS devices, actuators, sensors, or transducers are manufactured in the future.

While the present invention has been described with reference to the specific examples, it is apparent to those skilled in the art that various modifications and alterations may be made within the technical spirit of the present invention, and these modifications and alterations belong to the appended claims.

### DESCRIPTION OF REFERENCE NUMERALS

1 and 2: Heterojunction semiconductor substrate of first embodiment and second embodiment
10 and 11: Semiconductor substrate
20, 20A, 20B, 21, 21A, and 21B: Metal layer
200 and 201: Conductive metal oxide layer
30 and 31: Epitaxial oxide layer
40: Sacrificial layer
50: Oxide single crystal substrate

What is claimed is:

1. A heterojunction semiconductor substrate with excellent dielectric properties comprising:
a semiconductor substrate;
a metal layer;
a conductive metal oxide layer; and
an epitaxial oxide thin film layer.

2. The heterojunction semiconductor substrate of claim 1, wherein the conductive metal oxide layer includes a metal capable of forming a Schottky contact with the epitaxial oxide thin film layer.

3. The heterojunction semiconductor substrate of claim 1, wherein the conductive metal oxide layer is amorphous or crystalline.

4. The heterojunction semiconductor substrate of claim 1, wherein the metal layer is a monolayer or laminated structure composed of one or two or more elements selected from the group consisting of Au, Al, W, Ti, Cr, Pt, Cu, Ni, Mo, Ta, Nb, and La.

5. The heterojunction semiconductor substrate of claim 1, wherein the metal layer is formed of a laminated structure of an A layer/B layer/A′ layer, the A layer and the A′ layer are formed of a metal adhesion layer with a thickness of 5 to 20 nm, and the B layer is formed of a metal bonding layer with a thickness of 20 nm to 1 μm.

6. The heterojunction semiconductor substrate of claim 5, wherein the laminated structure is an A layer/B layer/A′ layer structure,
wherein the A layer and the A′ layer are the same or different and one or more selected from the group consisting of Ti, Cr, Cu, Ni, Pt and Cr, and
wherein the B layer is any one selected from the group consisting of Au, Mo, Ta, Nb, La, W and CuW.

7. The heterojunction semiconductor substrate of claim 1, wherein the metal layer has a total thickness of 5 to 1500 nm.

8. The heterojunction semiconductor substrate of claim 1, wherein the epitaxial oxide thin film layer has a crystallinity with a full width at half maximum (FWHM) value of 0.3° or less when an omega (ω) rocking curve is measured for a peak with highest diffraction peak intensity, in case of the measurement with a 0−2θmode of an X-ray diffractometer.

9. The heterojunction semiconductor substrate of claim 1, wherein the epitaxial oxide thin film layer is formed of a perovskite piezoelectric oxide with a lattice constant of 0.3 to 0.45 nm.

10. The heterojunction semiconductor substrate of claim 9, wherein the perovskite piezoelectric oxide is formed of a material in which any one selected from the group consisting of Pb(Mg_{1/3},Nb_{2/3})O₃, PbZrO₃, PbTiO₃, SrTiO₃, SrRuO₃, BaTiO₃ and BiFeO₃, a solid solution thereof, or a dopant has been added.

11. The heterojunction semiconductor substrate of claim 9, wherein the perovskite piezoelectric oxide includes a piezoelectric single crystal of a perovskite-type crystal structure (ABO₃) having a composition of Chemical formula 1 below:
[A_{1-(a+1.5b)}BₐC_{b}][(MN)_{1-x-y}(L)_{y}Tiₓ]O₃ Chemical Formula 1
In the formula above, A is Pb or Ba,
B is one or more species selected from the group consisting of Ba, Ca, Co, Fe, Ni, Sn, and Sr,
C is one or more species selected from the group consisting of Co, Fe, Bi, La, Ce, Pr, Nd, Pm, Sm, Eu, Gd, Tb, Dy, Ho, Er, Tm, Yb, and Lu,
L is a single or mixed form selected from Zr or Hf,
M is one or more species selected from the group consisting of Ce, Co, Fe, In, Mg, Mn, Ni, Sc, Yb, and Zn,
N is at least one species selected from the group consisting of Nb, Sb, Ta, and W,
0<a≤0.10,
0<b≤0.05,
0.05≤x≤0.58,
0.05≤y≤0.62.

12. The heterojunction semiconductor substrate of claim 11, wherein the piezoelectric single crystal is a piezoelectric single crystal of 0.01≤a≤0.10, 0.01≤b≤0.05 in the formula.

13. The heterojunction semiconductor substrate of claim 1, wherein the epitaxial oxide thin film layer is a poreless thin film layer formed of a perovskite piezoelectric oxide including zirconium (Zr) grown by a solid phase growth method.

14. The heterojunction semiconductor substrate of claim 1, wherein the semiconductor substrate is any one selected from a Si substrate, a silicon on insulator (SOI) substrate, a Si substrate on which a CMOS-based circuit is formed, or a SOI substrate on which a CMOS-based circuit is formed, a sapphire substrate, a GaAs, AlN, Ge, SiGe, GaN, AlGaN, SiC, AlSiC wafer, a Ni, Cu, Nb, Mo, Ta, La, CuW, NiW, or NiCu plate, or a laminated structure including the plate material.

15. A method of manufacturing a heterojunction semiconductor substrate, the method comprising:
forming a sacrificial layer 40, an epitaxial oxide thin film layer 30, a conductive metal oxide layer 200, and a metal layer 20A sequentially on an oxide single crystal substrate 50;
forming a metal layer 20B on a semiconductor substrate 10;
bonding the metal layer 20A on the oxide single crystal substrate and a metal layer 20B on the semiconductor substrate such that the metal layer 20A and the metal layer 20B face each other; and
separating the oxide single crystal substrate 50 by etching and removing the sacrificial layer 40 after the bonding.

16. A method of manufacturing a heterojunction semiconductor substrate, the method comprising:
forming a sacrificial layer 40, an epitaxial oxide thin film layer 30, a conductive metal oxide layer 201, and a metal layer 21A sequentially on an oxide single crystal substrate 50;
patterning the epitaxial oxide thin film layer 30, the conductive metal oxide layer 201, and the metal layer 21A that have been formed into a plurality of lattice cells;
forming a metal layer 21B on a semiconductor substrate 10;
bonding the metal layer 21A on the oxide single crystal substrate and the metal layer 21B on the semiconductor substrate such that the metal layer 21A and the metal layer 21B face each other; and
separating the oxide single crystal substrate 50 by etching and removing the sacrificial layer 40 after the bonding.

17. The method of claim 15, wherein the oxide single crystal substrate is surface treated to a surface roughness of 1 nm or less.

18. The method of claim 16, wherein the oxide single crystal substrate is surface treated to a surface roughness of 1 nm or less.

19. The method of claim 15, wherein the bonding is performed in a manner in which the metal layers of each substrate are aligned to face each other at the same position, mechanically bonded, and then pressed and heated.

20. The method of claim 16, wherein the bonding is performed in a manner in which the metal layers of each substrate are aligned to face each other at the same position, mechanically bonded, and then pressed and heated.
